(19) United States
(12) Patent Application Publication
(10) Pub. No.: US 2021/0268644 A1
(43) Pub. Date: Sep. 2, 2021

(54) ROBOT ARM AND ROBOT

(71) Applicant: Tokyo Robotics Inc., Tokyo (JP)

(72) Inventors: Takamitsu TAKAGI, Tokyo (JP); Yuki MATSUO, Tokyo (JP); Yoshihiro SAKAMOTO, Tokyo (JP)

(73) Assignee: Tokyo Robotics Inc., Tokyo (JP)

(21) Appl. No.: 17/265,341

(22) PCT Filed: Jun. 4, 2019
(86) PCT No.: PCT/JP2019/022233

§ 371 Date: Feb. 2, 2021

(30) Foreign Application Priority Data
Aug. 9, 2018 (JP) 2018-150752

(51) Int. Cl. B25J 9/12; H02K 5/06; H02K 11/33; H05K 7/20

(52) U.S. Cl. CPC B25J 9/12; H02K 5/06; H02K 2211/03; H05K 7/2039; H02K 11/33

(57) ABSTRACT

A robot arm and the like are provided which can be appropriately driven even by using a DC power supply having a lower output voltage than a general commercial power supply. The robot arm is provided with a housing and includes: an AC motor having a predetermined drive voltage; and a board having a drive circuit mounted thereon, the drive circuit driving the AC motor by converting a DC voltage into an AC voltage, the DC voltage being output from a power supply providing a predetermined DC voltage output. The board is arranged in surface contact with a predetermined surface of the housing.

### TECHNICAL FIELD

The present invention relates to, for example, an electric robot arm or robot.

### BACKGROUND ART

In recent years, various robot arms have been active in industry (for example, Patent Literature 1). Many of such kinds of robot arms are installed in factories or the like.

An AC servomotor is often used for driving a conventional stationary robot arm. On the other hand, a commercial power supply provided in factories or the like is an AC power supply, and its power supply voltage is generally about 200 [V] (or about 400 [V]). Therefore, for the conventional stationary robot arm, the AC servomotor is driven by converting an AC power supply voltage into a DC voltage by a converter including a rectifying and smoothing circuit, and then performing conversion again into an AC voltage of any frequency by an inverter.

On the other hand, in recent years, there has been an increasing demand for a mobile robot arm or a mobile manipulator which is not a stationary type but has a battery and the like.

### CITATION LIST

### Non Patent Literature

Non Patent Literature 1: Albu-Schaffer, et al, “The DLR Lightweight Robot-Design and Control Concepts for Robots in Human Environments,” the Federal Republic of Germany, Emerald Group Publishing Limited, 2007, Industrial Robot: An International Journal, Vol. 34 Issue: 5, pp. 376-385

### SUMMARY OF INVENTION

### Technical Problem

However, this type of battery is generally a DC power supply, and its output voltage is generally about 12 [V] or 24 [V], which is lower than that of a commercial power supply or the like. If an AC servomotor is driven with the same degree of output as that of the conventional stationary robot arm by using this battery, for example, a large current flows in the inverter circuit and as a result, circuit elements may generate excessive heat.

The present invention has been made to solve the above-described technical problem, and its object is to provide a robot arm and the like that can be appropriately driven even by using a DC power supply having a lower output voltage than a general commercial power supply.

### Solution to Problem

The above-described technical problem can be solved by a robot arm and a robot which have the following configuration.

More specifically, the robot arm according to the present invention is a robot arm provided with a housing and includes: an AC motor having a predetermined drive voltage; and a board having a drive circuit mounted thereon, the drive circuit driving the AC motor by converting a DC voltage into an AC voltage, the DC voltage being output from a power supply providing a predetermined DC voltage output. The board is arranged in surface contact with a predetermined surface of the housing.

According to this configuration, heat generated due to driving of the motor on the board can be efficiently dissipated using the housing. Therefore, for example, it is possible to provide the robot arm and the like that can be appropriately driven even by using a DC power supply having a lower output voltage than a general commercial power supply voltage. In addition, for example, a low-voltage power supply that is likely to cause an increase in the amount of heat generation in the drive circuit can be used and therefore, a battery-mounted robot arm can be realized. Here, the term, housing, is a concept that includes not only the housing itself, that is, one that is integrally formed as a housing but also other members that can form a heat path from the board to the housing and are fixed to the housing.

The predetermined surface may be arranged on an inner surface of the housing.

According to this configuration, the board is arranged on an inner peripheral surface of the housing and therefore, its safety is improved and further, a good appearance is not spoiled.

The above predetermined surface may be provided on a convex portion that protrusively extends from the inner peripheral surface of the housing.

According to this configuration, heat generated due to driving of the motor on the board can be efficiently dissipated using the convex portion.

The housing may have an annular convex portion that protrusively extends from the inner peripheral surface of the housing in such a manner as to surround a rotation center axis of the AC motor, the predetermined surface may be on the annular convex portion and may be a surface orthogonal to the rotation center axis of the AC motor, and the board may be annular and may be arranged in surface contact with the predetermined surface.

According to this configuration, the board can be annularly arranged to avoid a rotation center part and therefore, miniaturization of the robot arm can be achieved as well as a heat dissipation effect.

A contact surface of the board with the housing may be made of metal.

According to this configuration, efficient heat dissipation can be achieved through metal that generally has a good thermal conductivity.

The contact surface of the board with the housing may be made of aluminum or aluminum alloy.

According to this configuration, efficient heat dissipation can be achieved through aluminum or aluminum alloy that generally has a good thermal conductivity.

The contact surface of the board with the housing may be made of coper or copper alloy.

According to this configuration, efficient heat dissipation can be achieved through copper or copper alloy that generally has a good thermal conductivity.

Grease may be interposed between a contact surface of the board with the housing and the predetermined surface.

According to this configuration, heat conduction from the board to the housing can be surely performed and therefore, more efficient heat dissipation can be achieved.

The output voltage of the power supply may be 50 V or less.

According to this configuration, heat generated due to driving of the motor on the board can be efficiently dissipated using the housing even when a low voltage power supply whose output voltage is lower than a general commercial power supply voltage is used.

The output voltage of the power supply may be 24 V or 48 V.

According to this configuration, even when a relatively low voltage source for 24 V or 48 V is used, a problem in connection with heat generation of the board will not occur and therefore, the battery-mounted robot arm can be realized.

The housing may be made of metal.

According to this configuration, efficient heat dissipation can be achieved through metal that generally has a good thermal conductivity.

The board may have, in its inside, a metal laminar core member.

According to this configuration, heat propagates planarly through the laminar core member and therefore, efficient heat dissipation can be achieved.

The robot arm may be a multi-joint robot arm that is configured by coupling a perpendicular joint unit that when the robot arm extends, arranges the AC motor perpendicularly to an installation surface and causes rotation around an axis of the robot arm, and a horizontal joint unit that when the robot arm extends, arranges the AC motor horizontally to the installation surface and causes a bending operation of the robot arm; the horizontal joint unit may include a first housing space that is formed by a housing portion which including and supporting the motor, and a second housing space that is formed by a housing portion arranged adjacent to the first housing space and is accessible through a removable cover portion arranged on a housing of the horizontal joint unit; and the board may be in surface contact with an inner surface of the second housing space.

According to this configuration, while efficient heat dissipation is achieved, board maintenance and replacement are facilitated by removing a cover of the horizontal joint unit where maintenance is more easily performed than the vertical joint unit.

The drive circuit mounted on the board may drive the AC motor for the perpendicular joint unit and the AC motor for the horizontal joint unit.

According to this configuration, both the motor provided on the perpendicular joint unit and the motor provided on the vertical joint unit are driven by the drive circuit provided on the board within the horizontal joint unit and therefore, the perpendicular joint unit especially required to be miniaturized can be miniaturized or shortened.

In addition, the present invention can be considered also as a robot. More specifically, the robot according to the present invention is a robot provided with a housing and includes: an AC motor having a predetermined drive voltage; and a board having a drive circuit mounted thereon, the drive circuit driving the AC motor by converting a DC voltage into an AC voltage, the DC voltage being output from a power supply providing a predetermined DC voltage output. The board is arranged in surface contact with a predetermined surface of the housing.

### Advantageous Effects of Invention

According to the present invention, a robot arm and the like can be provided which can be appropriately driven even by using a DC power supply having a lower output voltage than a commercial power supply.

### BRIEF DESCRIPTION OF DRAWINGS FIG. 1 is an external view of a robot arm.

FIG. 2 is an external view of the robot arm in a bent state.

FIG. 3 is a block diagram of an electrical and communication system.

FIG. 4 is a block diagram of a power supply unit.

FIG. 5 is an external perspective view of a housing of a joint unit.

FIG. 6 is a partially exploded perspective view of the joint unit.

FIG. 7 is a diagram for describing a surface contact mode of a drive circuit board.

FIG. 8 is a cross-sectional view of the board.

FIG. 9 is modifications of the board.

### DESCRIPTION OF EMBODIMENTS

Hereinafter, a preferred embodiment of the present invention will be described with reference to accompanying FIG. 1 to FIG. 9.

### 1. First Embodiment

FIG. 1 is an external view of a robot arm 1 and FIG. 1(a) is a front view of the robot arm 1 and FIG. 1(b) is a perspective view of the robot arm 1. As is clear from the views, the robot arm 1 includes a housing that is approximately circular in a cross section and has seven joints that are driven by seven drive units 100 arranged between a base member 10 to an end effector attaching portion 26 at a terminus. In addition, as described later, the robot arm 1 is connected to a 24 [V] DC low voltage power supply which is provided inside or outside it. Note that in each of the drive units 100, which is a unit constituted of a motor and a decelerator, a brake and the like may be combined.

At an upper end of a first tubular housing 10 which is a tubular housing arranged at a base end of the robot arm 1 and having the same center as a center axis of the robot arm 1, a first housing 11 is rotatably coupled around the center axis of the robot arm 1 via a first rotating coupling member 101 that rotates and provides a function of coupling to another housing. Inside the first tubular housing 10, a drive unit 100 that makes the first rotating coupling member 101 rotate around the center axis is arranged. This drive unit 100 has its rotation center axis arranged so as to be perpendicular to a reference surface at the time of extension of the robot arm 1; and forms a perpendicular joint unit together with the first tubular housing 10, the first rotating coupling member 101, and the like.

The first housing 11 is rotatably coupled to a second housing 13 via the drive unit 100. On outer side surfaces in a horizontal direction of a coupling portion of the first housing 11 and the second housing 13 with the drive unit 100, a first cover member 12 and a second cover member 14 which are removable are respectively provided. Note that the drive unit 100 provided between the first housing 11 and the second housing 13 is arranged so as to make its rotation axis horizontal to a reference surface and forms a perpendicular joint unit together with the first housing 11, the second housing 13, the first cover member 12, the second cover member 14, and the like.

At an upper end of a second tubular housing 15 which is a tubular housing coupled to the second housing 13 and having the same center as the center axis of the robot arm 1, a third housing 16 is rotatably coupled around the center axis of the robot arm 1 via a second rotating coupling member 151 that rotates and provides a function of coupling to another housing. Inside the second tubular housing 15, a drive unit 100 that makes the second rotating coupling member 151 rotate around the center axis of the robot arm 1 is arranged. This drive unit 100 has its rotation center axis arranged so as to be perpendicular to a reference surface at the time of extension of the robot arm 1; and forms a perpendicular joint unit together with the second tubular housing 15 and the second rotating coupling member 151.

The third housing 16 is rotatably coupled to a fourth housing 18 via a drive unit 100. On outer side surfaces in a horizontal direction of a coupling portion of the third housing 16 and the fourth housing 18 with the drive unit 100, a third cover member 17 and a fourth cover member 19 which are removable are respectively provided. Note that the drive unit 100 provided between the third housing 16 and the fourth housing 18 is arranged so as to make its rotation axis horizontal to a reference surface and forms a horizontal joint unit together with the third housing 16, the fourth housing 18, the third cover member 17, the fourth cover member 19, and the like.

At an upper end of a third tubular housing 20 which is a tubular housing coupled to the fourth housing 18 and having the same center as the center axis of the robot arm 1, a fifth housing 21 is rotatably coupled around the center axis of the robot arm 1 via a third rotating coupling member 201 that rotates and provides a function of coupling to another housing. Inside the third tubular housing 20, a drive unit 100 that makes the third rotating coupling member 201 rotate around the center axis is arranged. This drive unit 100 has its rotation center axis arranged so as to be perpendicular to a reference surface at the time of extension of the robot arm 1; and forms a perpendicular joint unit together with the third tubular housing 20, the third rotating coupling member 201, and the like.

The fifth housing 21 is rotatably coupled to a sixth housing 23 via a drive unit 100. On outer side surfaces in a horizontal direction of a coupling portion of the fifth housing 21 and the sixth housing 23 with the drive unit 100, a fifth cover member 22 and a sixth cover member 24 which are removable are respectively provided. Note that the drive unit 100 provided between the fifth housing 21 and the sixth housing 23 is arranged so as to make its rotation axis horizontal to a reference surface and forms a horizontal joint unit together with the fifth housing 21, the sixth housing 23, the fifth cover member 22, the sixth cover member 24, and the like.

At an upper end of a fourth tubular housing 25 which is a tubular housing coupled to the sixth housing 23 and having the same center as the center axis of the robot arm 1, an end effector connecting portion 26 for connecting with an end effector such as a hand or a gripper is rotatably coupled around the center axis of the robot arm 1 via a fourth rotating coupling member 251 that rotates and provides a function of coupling to another housing. Inside the fourth tubular housing 25, a drive unit 100 that makes the fourth rotating coupling member 251 rotate around the center axis of the robot arm 1 is arranged. This drive unit 100 has its rotation center axis arranged so as to be perpendicular to a reference surface at the time of extension of the robot arm 1; and forms a perpendicular joint unit together with the fourth tubular housing 25, the fourth rotating coupling member 251, and the like.

Note that inside the horizontal joint unit, a control circuit board 55 and a drive circuit board 50 that perform not only control and driving of a drive unit 100 within the horizontal joint unit but also control and driving of an adjacent perpendicular joint unit are stored adjacent to the drive unit 100. More specifically, the control circuit board 55 and the drive circuit board 50 that perform control and driving of the drive unit 100 stored in the first housing 11 and the second housing 13 also perform control and driving of the drive unit 100 stored in the first tubular housing 10. In addition, the control circuit board 55 and the drive circuit board 50 that perform control and driving of the drive unit 100 stored in the third housing 16 and the fourth housing 18 also perform control and driving of the drive unit 100 stored in the second tubular housing 15. Furthermore, the control circuit board 55 and the drive circuit board 50 that perform control and driving of the drive unit 100 stored in the fifth housing 21 and the sixth housing 23 also perform control and driving of the drive unit 100 stored in the fourth tubular housing 25. Note that in the present embodiment, the drive unit 100 in the third tubular housing 20 is controlled and driven by a control circuit board and drive circuit board for single axis control, not illustrated, which are arranged in the third tubular housing 20.

According to this configuration, the control circuit board 55 and the drive circuit board 50 are provided together in the horizontal joint unit and therefore, an increase in the length in an axis direction of the robot arm 1 can be prevented, thereby achieving miniaturization of the robot arm 1. In addition, without performing an extensive disassembly or the like, the control circuit board 55 and the drive circuit board 50 that perform control and driving of the horizontal joint unit and its adjacent perpendicular joint unit can be easily accessed by removing the cover member (12, 17, 22), thereby facilitating program writing, maintenance, and the like.

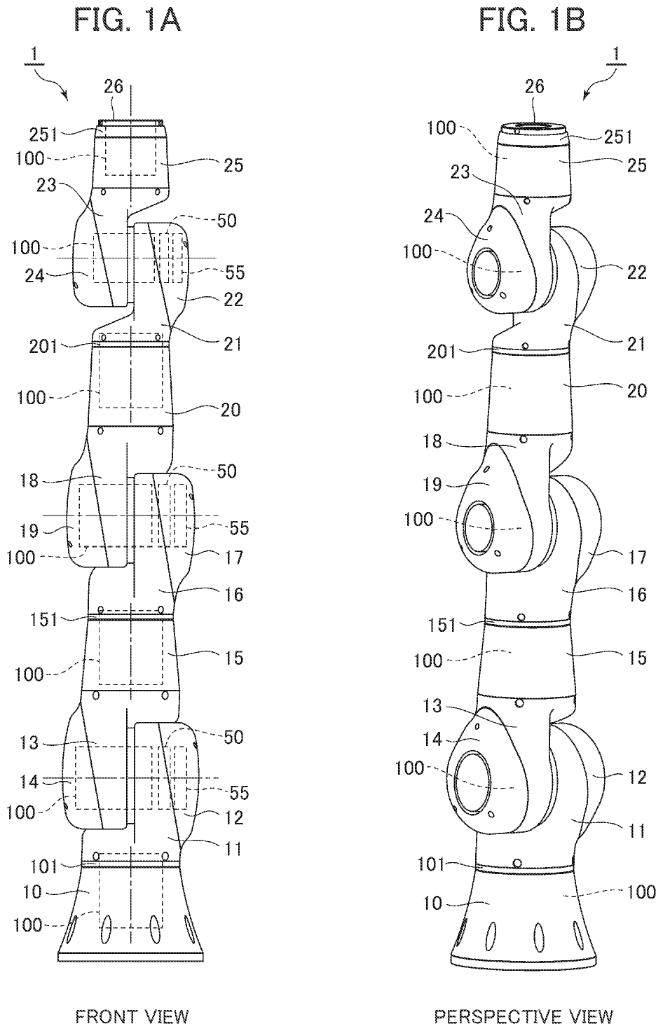

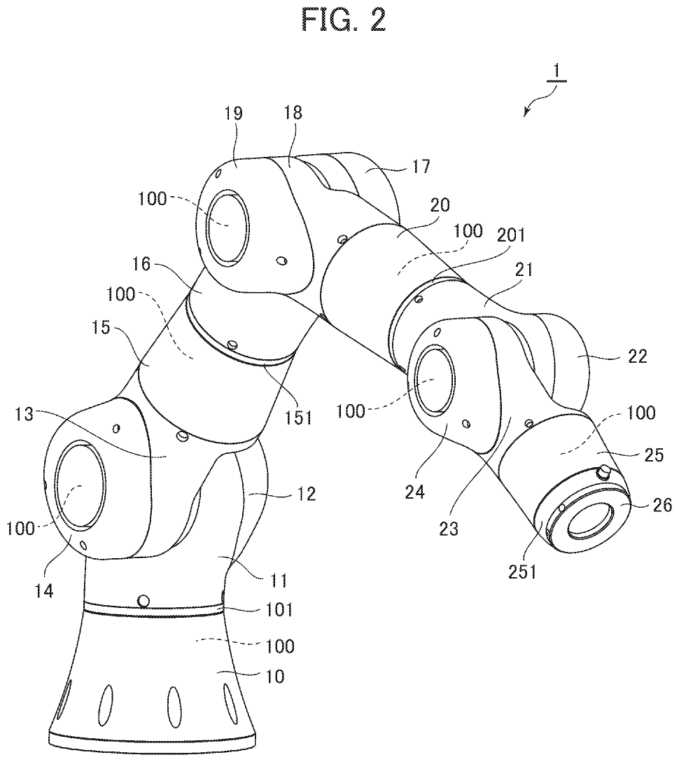

FIG. 2 is an external perspective view that shows the robot arm 1 in a state in which each joint is bent. As is clear from this figure, the robot arm 1 can freely bend each joint by operating each of the drive units 100 provided inside each of joint portions of the robot arm 1 in response to an instruction from a control unit which is not illustrated.

Note that any of housings of the robot arm 1 is made of an aluminum alloy. In the present embodiment, it is described that all the drive units 100 provided in the robot arm 1 are the same; but the present invention is not limited to this embodiment. Therefore, for example, while the structure is substantially the same, the size of each of the drive units 100 may be changed according to each joint space, a required torque, or the like. In addition, the housing of the robot arm 1 is not limited to being of an aluminum alloy and may be another metal, for example, a magnesium alloy or the like.

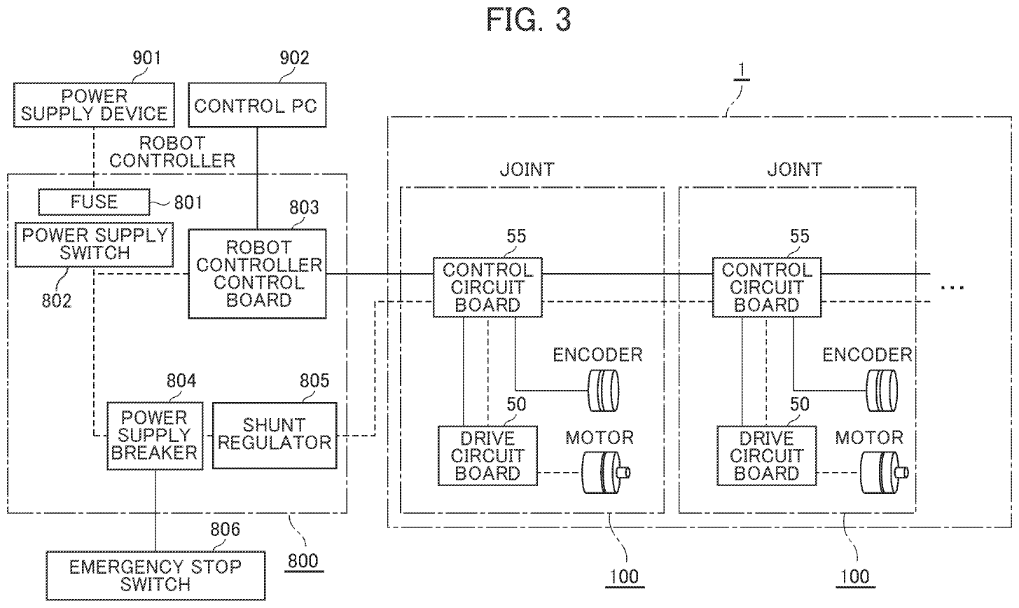

FIG. 3 is a block diagram of an electrical and communication system of the robot arm 1. As is clear from this figure, the robot arm 1 is connected to a power supply device 901 and a control PC 902 via a robot controller 800 (master controller). Inside the robot arm 1, a plurality of joint units including drive units 100 are provided in series and a signal line and a power supply line are distributed to each of the drive units 100.

An instruction signal and the like from the control PC 902 are transmitted to a motor of each of the drive units 100 via the robot controller control board 803 on which a robot controller CPU and the like are mounted and the control circuit board 55 of each joint. In addition, from an encoder provided in each joint, information such as a joint angle can be obtained and the information is transmitted to the control PC 902 via the control circuit board 55, the robot controller control board 803, and the like. More specifically, in the present embodiment, processing related to the overall operation of a top arm is performed by the control PC 902 and processing related to a plurality of joints (for example, position control, trajectory control, or speed control) is performed by the robot controller control board 803 and processing at each joint level is performed by the control circuit board 55 of each joint.

In addition, power from the power supply device 901 is supplied to the robot arm 1 via the robot controller 800. Inside the robot controller 800, sequentially provided on a path reaching from a power supply input side to its output side are: a fuse 801 that protects the device from overcurrent; a power supply switch 802 that switches on/off of power supply; a power supply breaker 804 that interrupts power supply by operation of an emergency stop switch 806 in emergency; and a shunt regulator 805 that prevents a regenerative current from a load (robot arm 1) side. The power supplied to the robot arm 1 is supplied to the control circuit board 50 and drive circuit board 55 of each joint and drives motors and the like. More specifically, the drive circuit board 55 at least performs such processing as converting a DC voltage which is input via the inverter circuit and the like into an AC voltage and performs power supply to a 24 [V] driven motor.

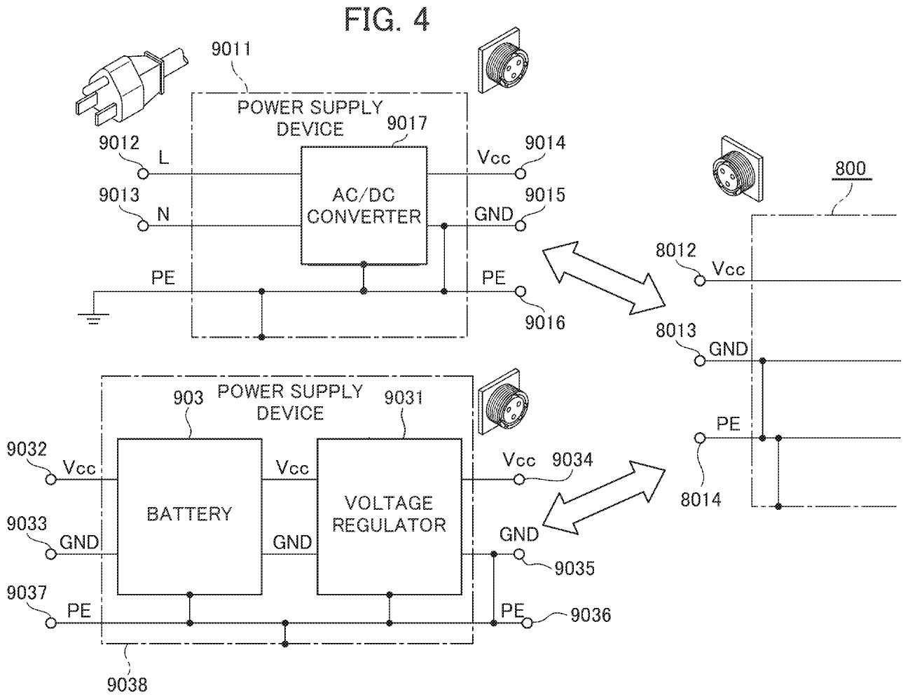

FIG. 4 is a block diagram that illustrates an electrical configuration of a part where power supply input is performed from a power supply unit, that is, the power supply device 901 to the robot controller 800. As is clear from this figure, the robot controller 800 has a connector that includes: a positive power supply (Vcc) terminal 8012; a ground (GND) terminal 8013; and a protective earth (PE) terminal 8014 for preventing an electric shock. Note that the ground (GND) terminal 8013 and the protective earth (PE) terminal 8014 are coupled to the housing. This connector is configured to be connectable, via a predetermined cable, with both a power supply device 9011 for commercial power supply and a rechargeable power supply device 9038 which will be described later.

At an upper part on the left in FIG. 4, the power supply device 9011 connectable to a commercial power supply is shown. The power supply device 9011 has a connector that includes a live (L) terminal 9012, a neutral (N) terminal 9013, and a protective earth (PE) terminal and is connectable to a commercial power supply. In addition, at an inside of it, an AC/DC converter 9017 that converts an input AC power supply into a DC power supply is included. The AC/DC converter 9017, to which a connector including a positive power supply (Vcc) terminal 9014, a ground (GND) terminal 9015, and a protective earth (PE) terminal 9016 is connected, is configured to be able to supply a DC voltage to the outside by having a cable or the like connected. Note that the output voltage of the power supply device 9011 is 24 [V].

On the other hand, on a lower part on the left of FIG. 4, the power supply device 9038 that performs power supply using a rechargeable battery 903 is shown. The battery 903 is configured to be rechargeable by a power supply which is not illustrated via a positive power supply (Vcc) terminal 9032 and a ground (GND) terminal 9033. The battery 903 which has been recharged, to which a voltage regulator 9031 for outputting a constant voltage is connected, can provide the constant voltage at the time of power supply. The voltage regulator 9031, to which a connector including a positive power supply (Vcc) terminal 9034, a ground (GND) terminal 9035, and a protective earth (PE) terminal 9036 is connected, is configured to be able to supply a DC voltage to the outside by having a cable or the like connected. Note that the protective earth (PE) terminal is electrically coupled with a housing of the power supply device 9038. In addition, the output voltage of the power supply device 9038 is 24 [V].

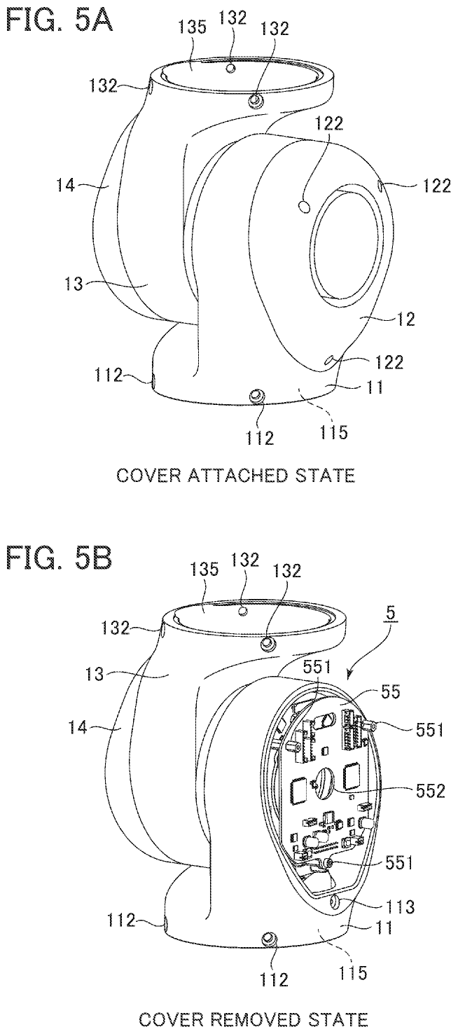

FIG. 5 is an external perspective view of a housing of a horizontal joint unit. 5A of this figure shows a state in which all cover members are mounted and 5B of this figure shows a state in which a first cover member 12 is removed.

As is clear from FIG. 5(b), by removing the first cover member 12 by loosening bolts inserted into three bolt holes 122 which are provided on the first cover member 12, a predetermined space 5 in which boards and the like are stored adjacent to a drive unit 100 is exposed. In the predetermined space 5, the control board 55 and the drive circuit 50 are stored. Note that in this figure, the control board 55 has a hole part 552 in its center and is fixed to the first housing 11 through bolts 551. More specifically, a configuration is made so as to allow easy access to the control board 55 and drive board 50 of the drive unit 100 stored in the housing by removing the first cover member 12.

According to this configuration, the cover of the horizontal joint unit in which maintenance is easily performed than the perpendicular joint unit can be removed and therefore, board maintenance and replacement, program writing, and the like are facilitated.

Note that at a lower end portion of the first housing 11 and an upper end portion of the second housing 13, circular opening portions 115 and 135 are provided, where end portions of joint units to be coupled to the circular opening portions 115 and 135 are brought into engagement and fixed using bolt holes 112 and 132. In addition, the positions of the bolt holes 122 are matched with both hole parts of head portions of the fixing bolts 551 for fixing the control board 55 to the first housing 11 and a bolt hole 113 which is provided closer to a base portion on a circumferential side surface of the first housing 11.

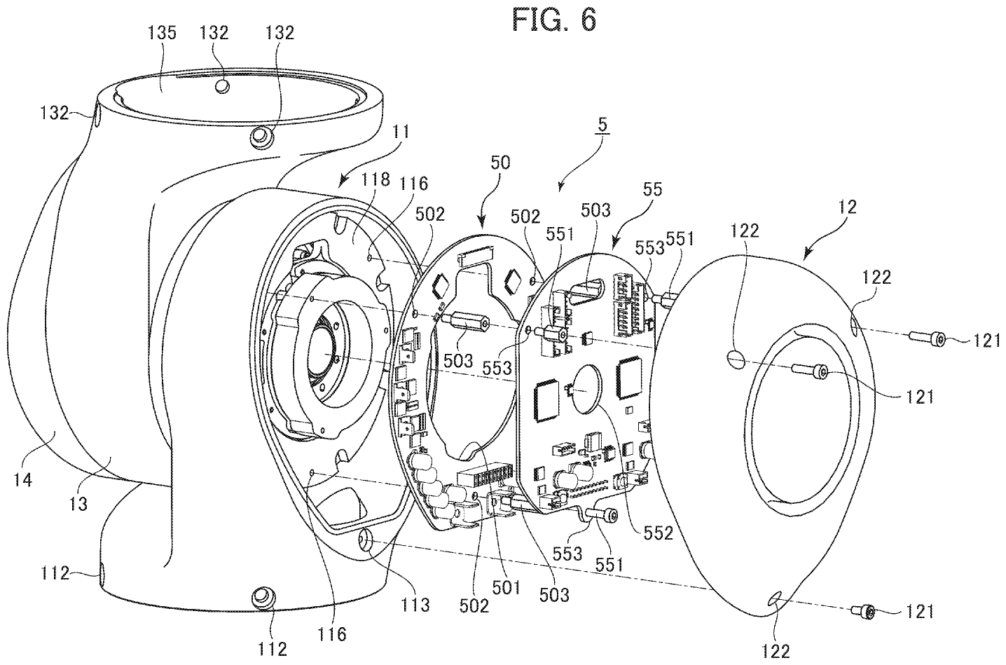

FIG. 6 is a partially exploded perspective view of the horizontal joint unit. As is clear from this figure, the horizontal joint unit stores the control circuit board 55 and the drive circuit board 50 in the predetermined space 5 which is exposed by removing the first cover member. Note that the control boards 55 are sequentially connected by a cable which is not illustrated and serial communication is performed.

The horizontal joint unit has an annular convex portion 118 that annularly protrudes from an inner side of a circumferential surface of a side surface opening portion. The drive circuit board 50 is arranged so as to be in surface contact with a surface in axial direction of this annular convex portion 118. The drive circuit board 50 is a printed board having a hole part 501 at its center and is fixed by inserting bolts 503, which also service as a spacer to the control circuit board 55, into fixing holes 116 on a surface in an axial direction of the annular convex portion 118 through insertion holes 502. The control circuit board 55 is arranged between the drive circuit board 50 and the first cover member 12 and is fixed by inserting the bolts 551 into bolt holes 553 and fixing to head portions of the bolts 503 for fixing the drive circuit board 50.

The control board 55 is a board that includes at least a circuit or a circuit element such as a microcomputer that controls each of the drive units 100. In addition, the drive circuit board 50 is a board that is connected to a DC power supply and performs power supply to a motor; and includes a circuit or a circuit element such as an inverter circuit that has a function of converting DC into AC. When an attempt to achieve a robot arm output at the same degree as the output of the robot arm 1 in using a commercial power supply (200 [V] or 400 [V] AC) is made in a state of connecting to the power supply device 9038 that outputs a low voltage (24 [V]) which is shown in FIG. 4, the motor and also the circuit element including an inverter circuit and the like generate heat due to an increase in current.

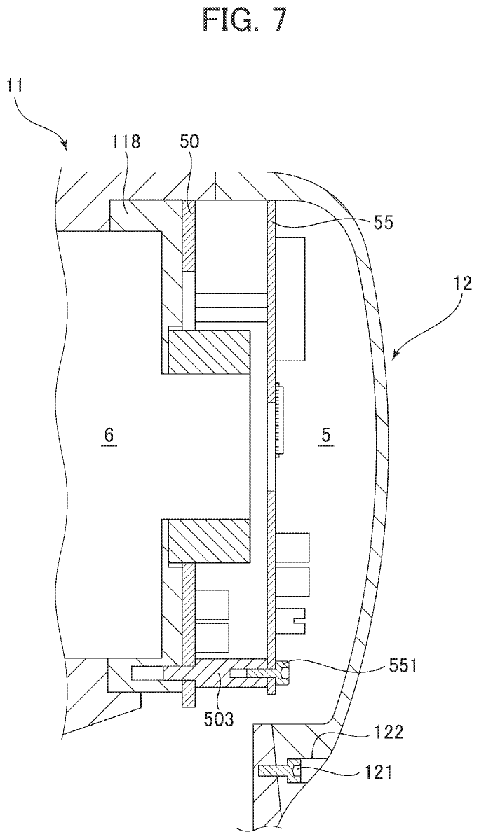

FIG. 7 is a diagram (cross-sectional view) for describing a surface contact mode of the drive circuit board 50. As is clear from this figure, at one side of the annular convex portion 118 (right side in the figure), the space 5 which is exposed by removing the cover member 12 is arranged and at the other side (left side in the figure), a space 6 which stores a drive unit 100 is adjacently arranged. The drive circuit board 50 is arranged so as to bring an aluminum alloy layer 519 on a rear surface of it, which is described later, into surface contact with a surface in the axial direction of the annular convex portion 118. Note that here, the annular convex portion 118 is closely fixed to a housing (first housing 11), to form a heat path from the drive circuit board 50 to the housing.

According to this configuration, even when a circuit element including an inverter circuit and the like generates heat, since the drive circuit board 50 is in surface contact with the annular convex portion 118 made of an aluminum alloy, the annular convex portion 118 and the housing serve as so-called a heat sink, allowing appropriate heat dissipation.

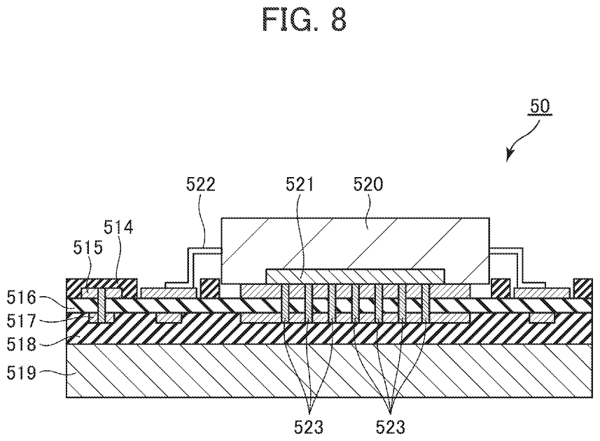

FIG. 8 is a schematic cross-sectional view of the drive circuit board 50. On the drive circuit board 50, a circuit pattern is three-dimensionally formed and a circuit element 520 (for example, switching element) is connected to the circuit pattern via a terminal 522. In order to dissipate heat generated on this circuit element 520, on a rear surface side of the circuit element 520, a bottom surface heat dissipation pad 521 and thermal vias 523 that are hole parts for heat dissipation are provided. The drive circuit board 50 has a multilayer structure; and from an upper surface side where the circuit element 520 is arranged, a first insulating layer (resist ink) 514, a first copper foil layer 515, a second insulating layer (board material) 516, a second copper foil layer 517, a third insulating layer (insulating adhesive layer) 518 are provided and on a lowest layer, or a rear surface side, the aluminum alloy layer 519 is arranged. Note that the aluminum alloy layer 519 may be one that is obtained by just attaching an aluminum alloy plate to a rear surface of the drive circuit board 50. In addition, aluminum may be used instead of an aluminum alloy.

According to this configuration, efficient heat dissipation can be achieved especially by using an aluminum alloy out of metals that generally have a good thermal conductivity.

### 2. Modification

The configurations of the robot arm and the robot according to the present invention are not limited to the above embodiment and their configurations can be appropriately modified without departing from the spirit of the present invention.

In the above-described embodiment, such a configuration has been described that the control circuit board 55 and the drive circuit board 50 for the drive unit 100 of a perpendicular joint unit are provided within a horizontal joint unit immediately thereabove. However, the present invention is not limited to this configuration. Therefore, they may be provided together within a horizontal joint unit that is more separate, not within the immediately above horizontal joint unit.

In the above-described embodiment, the drive circuit board 50 has a structure that allows heat to be easily dissipated by arranging a metal layer on its rear surface. However, the present invention is not limited to such a configuration.

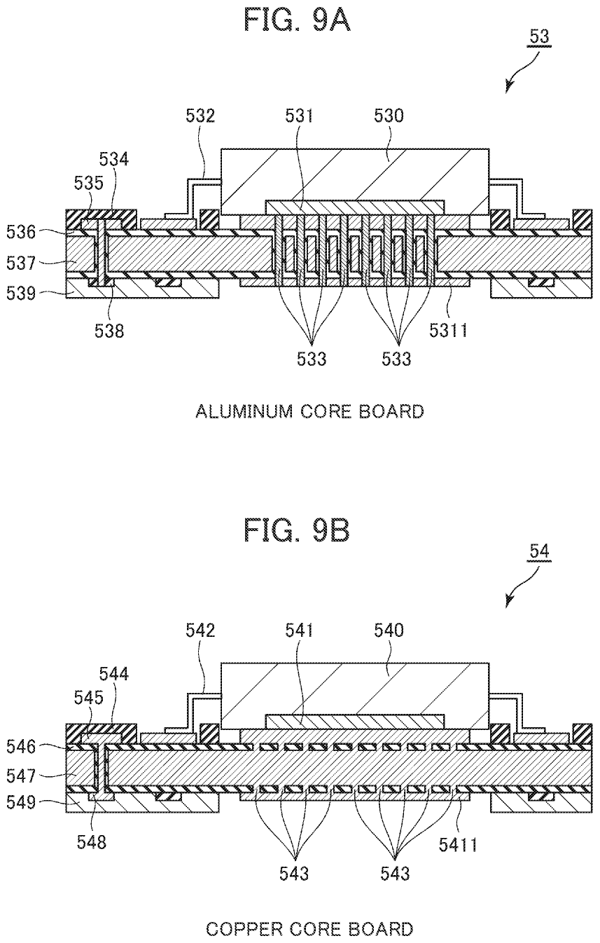

FIG. 9(a) is a schematic view of a cross section of a drive circuit board 53 in which a metal layer, especially an aluminum alloy layer 537 is arranged in the center. As with FIG. 8, in the drive circuit board 53, a circuit pattern is three-dimensionally formed and also a circuit element 530 (for example, switching element) is connected to the circuit pattern via a terminal 532. In order to dissipate heat generated on this circuit element 530, on a rear surface side of the circuit element 530, a bottom surface heat dissipation pad 531 and thermal vias 533 that are hole parts for heat dissipation are provided. The drive circuit board 53 has a multilayer structure; and from an upper surface side where the circuit element 530 is arranged, a first insulating layer (resist ink) 534, a first copper foil layer 535, a second insulating layer (insulating adhesive layer) 536, an aluminum alloy layer 537, a second copper foil layer 538, a third insulating layer (insulating adhesive layer) 539 are provided. According to this configuration, heat propagates planarly through the aluminum alloy layer 537 and therefore, heat dissipation is more easily performed.

FIG. 9(b) is a schematic view of a cross section of a drive circuit board 54 in which a metal layer, especially a copper layer 547 made of copper or a copper alloy is arranged in the center. As with FIG. 8, in the drive circuit board 54, a circuit pattern is three-dimensionally formed and also a circuit element 540 (for example, switching element) is connected to the circuit pattern via a terminal 542. In order to dissipate heat generated on this circuit element 540, on a rear surface side of the circuit element 540, a bottom surface heat dissipation pad 541 and hole parts 543 for heat dissipation are provided. The drive circuit board 54 has a multilayer structure; and from an upper surface side where the circuit element 540 is arranged, a first insulating layer (resist ink) 544, a first copper foil layer 545, a second insulating layer (insulating adhesive layer) 546, a copper layer 547, a second copper foil layer 548, and a third insulating layer (insulating adhesive layer) 549 are provided. According to this configuration, heat propagates planarly through the copper layer 547 and therefore, heat dissipation is more easily performed.

In addition, in the above-described embodiment, a configuration is such that between the drive circuit board 50 and the annular convex portion 118, just a close contact is made. However, the present invention is not limited to this configuration. Therefore, for example, grease may be interposed between the rear surface (aluminum alloy layer 519) of the drive circuit board 50 and the surface in the axial direction of the annular convex portion 118. According to this configuration, heat conduction from the drive circuit board 50 to the first housing 11 can be surely performed, and more efficient heat dissipation can be achieved.

### INDUSTRIAL APPLICABILITY

The present invention can be used in an industry for manufacturing a robot arm and the like.

### REFERENCE SIGNS LIST

1 robot arm
50 drive circuit board
55 control circuit board
100 drive unit

1. A robot arm provided with a housing, comprising:
an AC motor having a predetermined drive voltage; and
a board having a drive circuit mounted thereon, the drive circuit driving the AC motor by converting a DC voltage into an AC voltage, the DC voltage being output from a power supply providing a predetermined DC voltage output, wherein
the board is arranged in surface contact with a predetermined surface of the housing.

2. The robot arm according to claim 1, wherein the predetermined surface is arranged on an inner surface of the housing.

3. The robot arm according to claim 1, wherein the predetermined surface is provided on a convex portion that protrusively extends from an inner peripheral surface of the housing.

4. The robot arm according to claim 1, wherein
the housing has an annular convex portion that protrusively extends from an inner peripheral surface of the housing in such a manner as to surround a rotation center axis of the AC motor;
the predetermined surface is on the annular convex portion and is a surface orthogonal to the rotation center axis of the AC motor and
the board is annular and arranged in surface contact with the predetermined surface.

5. The robot arm according to claim 1, wherein a contact surface of the board with the housing is made of metal.

6. The robot arm according to claim 5, wherein the contact surface of the board with the housing is made of aluminum or an aluminum alloy.

7. The robot arm according to claim 5, wherein the contact surface of the board with the housing is made of copper or a copper alloy.

8. The robot arm according to claim 1, wherein grease is interposed between a contact surface of the board with the housing and the predetermined surface.

9. The robot arm according to claim 1, wherein an output voltage of the power supply is 50 V or less.

10. The robot arm according to claim 9, wherein the output voltage of the power supply is 24 V or 48 V.

11. The robot arm according to claim 1, wherein the housing is made of metal.

12. The robot arm according to claim 1, wherein the board has, in its inside, a metal laminar core member.

13. The robot arm according to claim 1, wherein
the robot arm is a multi-joint robot arm configured by coupling a perpendicular joint unit that when the robot arm extends, arranges the AC motor perpendicularly to an installation surface and causes rotation around an axis of the robot arm, and a horizontal joint unit that when the robot arm extends, arranges the AC motor horizontally to the installation surface and causes a bending operation of the robot arm;
wherein
the horizontal joint unit includes a first housing space that is formed by a housing portion which including and supporting the motor, and a second housing space that is formed by a housing portion arranged adjacent to the first housing space and is accessible through a removable cover portion arranged on a housing of the horizontal joint unit; and
the board is in surface contact with an inner surface of the second housing space.

14. The robot arm according to claim 13, wherein the drive circuit mounted on the board drives the AC motor for the perpendicular joint unit and the AC motor for the horizontal joint unit.

15. A robot provided with a housing, comprising:
an AC motor having a predetermined drive voltage; and
a board having a drive circuit mounted thereon, the drive circuit driving the AC motor by converting a DC voltage into an AC voltage, the DC voltage being output from a power supply providing a DC voltage output;
wherein
the board is arranged in surface contact with a predetermined surface of the housing.
